(19) United States
(12) Patent Application Publication
(10) Pub. No.: US 2011/0088754 A1
(43) Pub. Date: Apr. 21, 2011

(54) POLYURETHANE COATINGS FOR THERMALLY REGULATING AND THE USE THEREOF

(75) Inventors: Jens Krause, Mours Saint Eusebe (FR); Frank Muschiol, Leverkusen (DE)

(73) Assignee: Bayer MaterialScience AG, Leverkusen (DE)

(21) Appl. No.: 12/996,478

(22) PCT Filed: May 26, 2009
(86) PCT No.: PCT/EP2009/003718

§ 371 Date: Dec. 6, 2010

(30) Foreign Application Priority Data
Jun. 7, 2008 (DE) 10 2008 027 342.2

(51) Int. Cl. H01L 31/042; B32B 7/02; B01J 19/00; F16L 9/14; E04C 2/20

(52) U.S. Cl. 136/246; 428/213; 422/241; 138/149; 52/309.1

(57) ABSTRACT

The present invention relates to a polyurethane coating having pipes or hoses having a diameter of ≦95% of the thickness of the polyurethane coating, through which a medium for heat exchange flows.

The invention relates to polyurethane coatings having pipes or hoses with which the polyurethane itself or materials adjacent to the polyurethane can be thermally regulated by heat exchange by means of media flowing through the pipes/hoses, and to the use thereof.

The encapsulation of solar cells is currently an important technical theme which is being worked on intensively. The background is, inter cilia, to utilise both the electrical energy and the thermal energy as effectively as possible. The thermal energy that is released at the surface of the solar cell during the energy conversion of the solar cells reduces the electrical yield. This means that the hotter the surface, in particular in summer, the lower the current yield. Solar cells are accordingly in most cases more effective on a cold, sunny winter's day than on a hot summer's day. The yield of the solar cell can be increased by dissipating that heat. In addition, the dissipated heat can optionally be used. In principle, the cooling of solar cells is already known from DE-A 43 07 705 and DE-A 299 13 202. However, cooling in those cases is carried out externally and is only possible with a loss of transmission because steel cooling tubes or plastics hoses, for example, are used.

It was an object of the present invention effectively to encapsulate solar cells and effectively to dissipate, and optionally use, the heat that is produced.

It has been possible to achieve that object by means of the polyurethane coatings according to the invention.

The invention provides polyurethane coatings which are characterised in that they are provided with pipes or hoses, which are preferably arranged in parallel, having a diameter of ≦95% of the thickness of the polyurethane coating, preferably ≦80%, through which a medium for heat exchange flows.

The pipes or hoses can be in the form of round or flat pipes or hoses. Multichannel pipes or hoses can also be used as the pipes/hoses.

The preferred diameter of the pipes or hoses is from 2 to 20 mm in most applications of the polyurethane coating.

Particular preference is given to the use of glass pipes. Pipes/hoses of plastics material can also be used, however.

Liquids are preferred as the medium on account of their higher thermal capacity. However, gases, such as, for example, air, can also be used. Particularly preferred media (media for cooling or for heating) are non-corrosive, non-toxic media, such as, for example, water or silicone oil. Melts can also be used as media (because of their high thermal capacity). Hydrocarbons, chlorofluorocarbons, paraffin oils and other media known from the prior art, and blends thereof, can likewise be used here. Particularly preferably, the medium is a transparent medium.

It is also possible to use aggressive media as the medium, because the polyurethane is protected by the pipes/hoses and diffusion of the medium into the polyurethane is not possible.

The medium flowing through the pipes or hoses in the polyurethane can also be used as a heating medium by passing it through the pipes or hoses at elevated temperature, and the formation of condensation, for example, on the polyurethane, which is in particular transparent, is thus prevented.

In the case of cooling, the heat taken up by the media flowing through the pipes/hoses can be dissipated via heat exchangers and thus used, for example, to produce hot water.

When used in a solar module, the polyurethane protects both the solar cell and the pipes or hoses embedded in the polyurethane, in particular the glass pipes in so far as they are used. The solar cell can be encapsulated by the polyurethane in a technically simple manner without the efficiency of the solar cell being greatly impaired, because the polyurethane as well as the pipes/hoses and the medium can be transparent. The polyurethane, the pipes or hoses and the medium are transparent in particular when they are oriented towards the light source and, as in the case of a solar module, are to allow the light rays to pass through unhindered as far as possible. The polyurethane coatings according to the invention additionally have the advantage that they can be produced in a simple manner from transparent, castable, relatively scratch-resistant and resilient polyurethane.

The invention further provides solar modules comprising solar cells encapsulated in polyurethane that is transparent at least where it is oriented towards the light source, which solar modules are characterised in that the polyurethane is provided with pipes or hoses, which are preferably arranged in parallel, through which a medium for heat exchange flows, wherein the pipes and hoses and the medium are transparent at least where they are oriented towards the light source.

The solar module according to the invention has the advantage that the overall efficiency of the solar cell is increased because the efficiency can be increased by the active cooling of the solar cell.

The transparent polyurethane with the cooling medium in the pipes/hoses not only acts as a heat exchanger, however, but also protects the solar cells against impacts and scratches. Moreover, polyurethane has higher scratch resistance and higher flexibility compared with other plastics.

Compared with glass, the polyurethane coating has the advantage that it is not breakable and, in addition, is highly resilient.

Preferably, the transparent polyurethane coating is located on the side of the solar module that faces the sun. A transparent polyurethane coating is not necessary on the side that is remote from the sun. On the side that is remote from the sun there can be used any polyurethane materials known from the prior art, but also the polyurethane coating according to the invention.

The polyurethane coatings according to the invention can be used as coatings not only for the encapsulation of solar cells but also for the thermal regulation of reactors.

They can be used in the production of solar collectors and in the production and thermal regulation of greenhouses. The polyurethane coatings can be used as a coating for façades, floor coverings or the like, and also as pipe insulation.

The transparent polyurethane coatings are suitable for the production of transparent reactors. So-called algae reactors can be mentioned here by way of example. The algae produce oxygen in the reactors from CO₂ under the influence of light (photosynthesis). In order for the algae to work efficiently, a temperature of about 27° C. is to be maintained, which is kept constant by heat exchange via the reactor wall. Either the reactor wall consists of the transparent polyurethane coating according to the invention, or the reactor, which is made, for example, of glass, is coated with the polyurethane coating according to the invention.

The polyurethane coating according to the invention can also be used in the production of thermal insulation elements. Such thermal insulation elements can be used, for example, in the insulation of buildings. Paraffins in particular can be used as the heat exchange medium here. Said elements, for example in the form of windows or transparent exterior façades, can thus thermally regulate the interior of the building.

It is also possible to use as the polyurethane syntactic polyurethane, which can preferably be employed in the form of a coating for the production of pipe insulation, such as, for example, in the off-shore industry.

The polyurethane coating can preferably contain hollow microsphere bodies. The hollow microsphere bodies act as a thermal insulating medium in the polyurethane coating.

The coatings can be produced by processes known per se, by first taking the pipes/hoses and applying the polyurethane reaction mixture by casting, spraying or injection moulding.

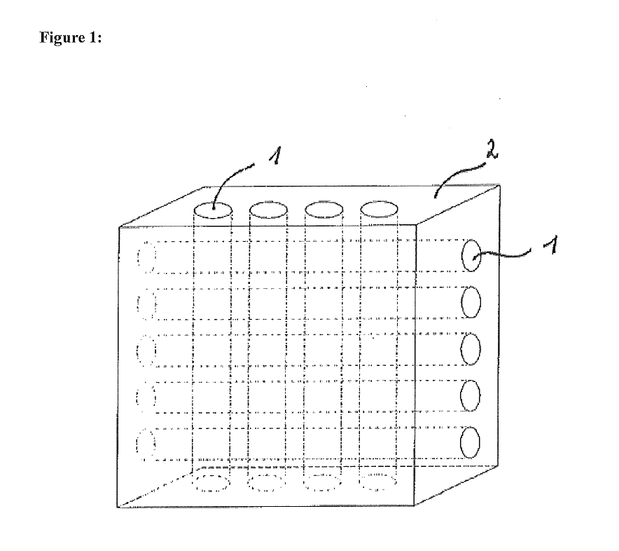

FIG. 1 shows a section of a coating according to the invention in which the pipes (1) are arranged in the polyurethane (2). The medium (not shown) flows through the pipes.

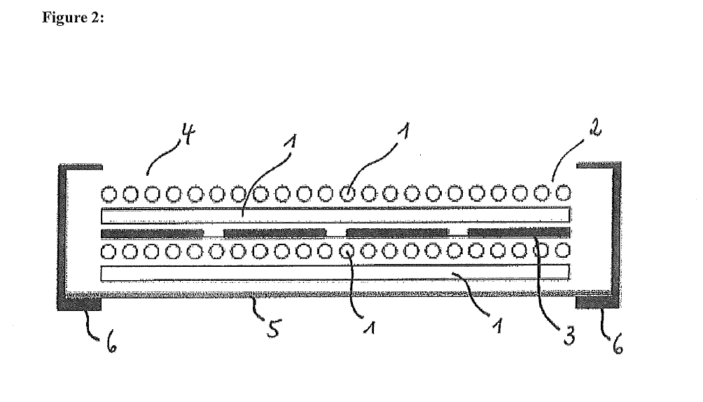

FIG. 2 shows a cross-section through a solar module having pipes (1) running transversely and longitudinally and solar cells (3) which are embedded in the polyurethane (2). The module is additionally protected towards the light source by a top layer (4) of glass or plastics material. The module additionally has a plate (5) for the purpose of protection and/or stabilisation, and a frame (6).

1.-6. (canceled)

7. A polyurethane coating, wherein the coating is provided with pipes or hoses having a diameter of ≦95% of the thickness of the polyurethane coating, through which a medium for heat exchange flows.

8. The polyurethane coating according to claim 7, wherein the pipes or hoses are arranged in the polyurethane.

9. The polyurethane coating according to claim 7, wherein the pipes or hoses are embedded in the polyurethane.

10. The polyurethane coating according to claim 7, wherein the pipes or hoses are arranged in parallel.

11. The polyurethane coating according to claim 7, wherein the polyurethane is transparent.

12. The polyurethane coating according to claim 7, wherein the pipes or hoses are transparent.

13. The polyurethane coating according to claim 7, wherein the medium is transparent.

14. The polyurethane coating according to claim 10, wherein the polyurethane, pipes or hoses, and the medium are transparent.

15. The polyurethane coating according to claim 7, wherein the pipes or hoses have a diameter of from 2 to 20 mm.

16. The polyurethane coating according to claim 7, wherein the pipes or hoses are glass.

17. The polyurethane coating according to claim 7, wherein the pipes or hoses are plastic.

18. A solar module or a solar collector comprising the polyurethane coating according to claim 7.

19. A façade comprising the polyurethane coating according to claim 7.

20. A floor covering comprising the polyurethane coating according to claim 7.

21. A greenhouse comprising the polyurethane coating according to claim 7.

22. An insulation for a pipe comprising the polyurethane coating according to claim 7.

23. A reactor comprising the polyurethane coating according to claim 7 disposed on a wall of the reactor.

24. A reactor wall consisting essentially of the polyurethane coating according to claim 7.

25. A solar module comprising solar cells which are encapsulated in polyurethane, wherein the polyurethane is transparent at least where it is oriented toward a light source, and wherein the polyurethane is provided with pipes or hoses through which a medium for heat exchange flows, wherein the pipes or hoses and the medium are transparent at least where they are oriented towards the light source.

26. The solar module according to claim 25, wherein the pipes or hoses are arranged in parallel.
